(19) United States
(12) Patent Application Publication
(10) Pub. No.: US 2025/0329646 A1
(43) Pub. Date: Oct. 23, 2025

(54) ELECTRONIC DEVICE AND METHOD OF FABRICATING AN ELECTRONIC DEVICE

(71) Applicant: STMicroelectronics International N.V., Geneva (CH)

(72) Inventors: Julien Amouroux, Aix en Provence (FR); Pascal Fornara, Pourrières (FR); Cloe Prudhomme, Gardanne (FR)

(21) Appl. No.: 19/082,802

(22) Filed: Mar. 18, 2025

(30) Foreign Application Priority Data
Apr. 18, 2024 (FR) FR2404022

(51) Int. Cl. H01L 23/528; H01L 21/768; H01L 23/522; H01L 23/532; H10D 64/23; H10D 84/83

(52) U.S. Cl. CPC H01L 23/5283; H01L 21/76816; H01L 21/7682; H01L 23/5226; H10D 64/258; H10D 84/83125; H01L 23/53214; H01L 23/53228; H01L 23/53257

(57) ABSTRACT

The present description concerns a method comprising providing a structure comprising a semiconductor substrate, conductive elements above the semiconductor substrate, a first intermetallic dielectric layer between the conductive elements, cavities in the first intermetallic dielectric layer between two adjacent conductive elements, and a second intermetallic dielectric layer above the first intermetallic dielectric layer and the cavities, the cavities being coupled together so as to form a continuous extended cavity between the two adjacent conductive elements, forming first, respectively second, ports running through the second intermetallic dielectric layer, extending to the cavities, respectively to the conductive elements, filling the first and second ports with a conductive material, the filling of the first ports filling the cavities, forming conductive regions coupled together, and thus a conductive track, and forming first conductive vias coupled to the conductive track, and filling the second ports forming second conductive vias coupled to the conductive elements.

### CROSS-REFERENCE TO RELATED APPLICATIONS

This application claims priority to French Patent Application No. 2404022, filed on Apr. 18, 2024, which application is hereby incorporated herein by reference.

### TECHNICAL FIELD

The present disclosure generally concerns semiconductor-based electronic devices, and methods of manufacturing semiconductor-based electronic devices.

In particular, the present disclosure concerns the interconnection structure in an electronic device.

### BACKGROUND

Semiconductor-based electronic devices generally comprise electronic components on top and/or inside of a semiconductor substrate layer. The substrate layer may, for example, be a solid semiconductor substrate or a silicon-on-insulator, or SOI, layer. Electronic components are generally manufactured in a front-end-of-line (FEOL) process. Once the FEOL process is complete, the manufacturing of the electronic device carries on by forming an interconnection structure comprising a network of electrical conduction paths intended to be coupled to the electronic components. This is referred to as, in the technical field, a back-end-of-line (BEOL) process.

The routing of the conduction paths in the BEOL process requires the forming of a plurality of metallization levels (or metallization layers) above the substrate layer, which comprises the electronic components formed during the FEOL process. The metallization comprises metal vias which extend perpendicularly to an upper surface of the substrate layer and metal lines which extend parallel to the upper surface of the substrate layer, a via enabling to couple metal lines of two different metallization levels. It is common practice to use copper (Cu) as a metallic material for the vias and the metal lines, although it is also known to use other metallic materials, such as aluminum (Al) for the metal lines and/or tungsten (W) for the vias, and possibly for barrier layers. The interconnection structure generally comprises a dielectric material at and/or between each metallization level, the vias and the metal lines being surrounded, and electrically insulated from each other, by the dielectric material.

As electronic components become smaller and electronic devices more complex, there is a corresponding increase in the complexity of the BEOL metallization, in particular to connect more and more electronic components, and in particular this may require an increase in the number of metallization levels. At the same time, it may be sought to have smaller and smaller interconnect structures to decrease the size of the electronic device.

### SUMMARY

There exists a need to improve semiconductor-based electronic devices, in particular to improve the interconnection of electronic components in an electronic device.

An embodiment overcomes all or part of the disadvantages of known electronic devices.

An embodiment provides a method of manufacturing an electronic device, the method comprising: the provision of a structure comprising a semiconductor substrate on top and inside of which are formed electronic components, first conductive elements above the semiconductor substrate, a first intermetallic dielectric layer between the first conductive elements, cavities in the first intermetallic dielectric layer between two first adjacent conductive elements among the first conductive elements, and a second intermetallic dielectric layer above the first intermetallic dielectric layer and cavities, the cavities being coupled together so as to form a continuous extended cavity between the two first adjacent conductive elements;
the forming of first ports and of second ports running through the second intermetallic dielectric layer, the first ports each extending all the way to one of the cavities and the second ports each extending all the way to one of the first conductive elements; the filling of the first and second ports with a conductive material, the filling of the first ports being performed so as to fill the cavities, forming conductive regions coupled together, and thus a conductive track, the filling of the first ports also forming first conductive vias coupled to the conductive track, and the filling of the second ports forming second conductive vias coupled to the first conductive elements.

According to an embodiment, the provision of the structure includes the forming of the cavities, which comprises: the forming of third ports running through the first intermetallic dielectric layer between the two first adjacent conductive elements, the forming of the third ports comprising an etching, for example an anisotropic etching and/or a dry etching; the widening of the third ports so as to form open cavities coupled together in the first intermetallic dielectric layer, the widening of the third ports comprising an etching, for example an isotropic etching and/or a wet etching; the forming of the second intermetallic dielectric layer over the open cavities and the first intermetallic dielectric layer, so as to close the open cavities.

According to an embodiment, the method comprises, prior to the forming of the third ports, the deposition of a first protection layer over the first intermetallic dielectric layer and the first conductive elements, followed by the forming of first openings in the first protection layer, the third ports being formed in line with the first openings, the forming of the first openings comprising an etching, for example an anisotropic etching and/or a dry etching.

According to an embodiment, the forming of the first and second ports comprises an anisotropic etching and/or a dry etching.

According to an embodiment, the provided structure comprises other cavities in the first intermetallic dielectric layer between two other first adjacent conductive elements among the first conductive elements, the second intermetallic dielectric layer also extending over the other cavities, the other cavities being coupled together and being not filled with the conductive material, so as to form a continuous extended cavity between the two other first adjacent conductive elements.

An embodiment provides an electronic device comprising: a semiconductor substrate on top and inside of which are arranged electronic components; first conductive elements above the semiconductor substrate; a first intermetallic dielectric layer between the first conductive elements; conductive regions extending at least across the thickness of the first intermetallic dielectric layer between two first adjacent conductive elements among the first conductive elements, the conductive regions being coupled together in the form of a conductive track; a second intermetallic dielectric layer over the first intermetallic dielectric layer, the first conductive elements, and the conductive track; first conductive vias running through the second intermetallic dielectric layer and coupled to the conductive track; second conductive vias running through the second intermetallic dielectric layer and coupled to the first conductive elements.

According to an embodiment, the electronic device further comprises other cavities in the first intermetallic dielectric layer between two other first adjacent conductive elements among the first conductive elements, the second intermetallic dielectric layer also extending above the other cavities, the other cavities being coupled together so as to form a continuous extended cavity between the two other first adjacent conductive elements.

The following embodiments may apply to the device or to the method.

According to an embodiment, the first conductive elements are insulated from one another by the first intermetallic dielectric layer in a first direction of a plane substantially parallel to the plane of the semiconductor substrate, and the conductive regions are coupled together in a second direction of the plane perpendicular to the first direction.

According to an embodiment, the conductive regions are also coupled together in the first direction of the plane.

According to an embodiment, the lateral edges of the first conductive elements are protected by a second protection layer.

According to an embodiment, the conductive regions also extend in a pre-metal dielectric layer located between the semiconductor substrate and the first intermetallic dielectric layer, for example between the electronic components and the first intermetallic dielectric layer.

According to an embodiment, contacts running through the pre-metal dielectric layer are coupled to the electronic components and to the first conductive elements, the conductive regions also extending between the contacts.

According to an embodiment, the conductive material comprises tungsten and/or the first conductive elements comprise copper or aluminum.

According to an embodiment, the first conductive elements and the first intermetallic dielectric layer form a first metallization level of an interconnection structure.

According to an embodiment, a second metallization level comprises second conductive elements coupled to the first conductive elements by the second conductive vias, and other second conductive elements coupled to the conductive track by the first conductive vias.

According to an embodiment, the conductive track and the first conductive vias are comprised in a circuit for controlling an electrical continuity between the conductive regions.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a longitudinal cross-section view schematically and partially showing an example of an electronic device;

FIG. 2, FIG. 3, FIG. 4, FIG. 5, FIG. 6, FIG. 7, FIG. 8, FIG. 9, and FIG. 10 are longitudinal cross-section views schematically and partially showing structures obtained at the end of successive intermediate steps of an example of a method of manufacturing an electronic device according to an embodiment;

FIG. 11 is a top view schematically and partially showing a structure capable of being obtained at the end of the step shown in FIG. 9;

FIG. 12 is a top view schematically and partially showing an electronic device capable of being obtained at the end of the step shown in FIG. 10;

FIG. 13A and FIG. 13B are top and three-dimensional views schematically and partially showing an electronic device according to an embodiment, such as the electronic device of FIG. 12, with additionally a second metallization level; and

FIG. 14 is a longitudinal cross-section view schematically and partially showing an electronic device according to another embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the manufacturing steps and the details of the electronic components, for example the drain, source, and gate regions for a MOS transistor, are not detailed, can be formed with usual electronic component manufacturing methods. Further, the manufacturing steps and the details of the interconnection structures are not described, since they can be formed with usual interconnection structure manufacturing methods.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the following description, the terms “insulating” and “conductive” respectively mean, unless otherwise specified, electrically insulating and electrically conductive.

In the following description, when reference is made to a substrate, reference is made, unless otherwise specified, to a semiconductor substrate. In the following description, when reference is made to a via, reference is made, unless otherwise specified, to a conductive via, for example a metal via.

In the following description, unless otherwise specified, a length corresponds to a dimension in a first direction, which corresponds to the longitudinal X direction indicated in the drawings, a width corresponds to a dimension in a second direction, orthogonal to the first X direction, which corresponds to the transverse Y direction indicated in the drawings, and a thickness or a depth corresponds to a dimension in a direction perpendicular to the first and second directions, which corresponds to the vertical Z direction indicated in the drawings. In the case of a MOSFET-type transistor, the longitudinal X direction corresponds to the direction of the channel length between a source region and a drain region of the transistor.

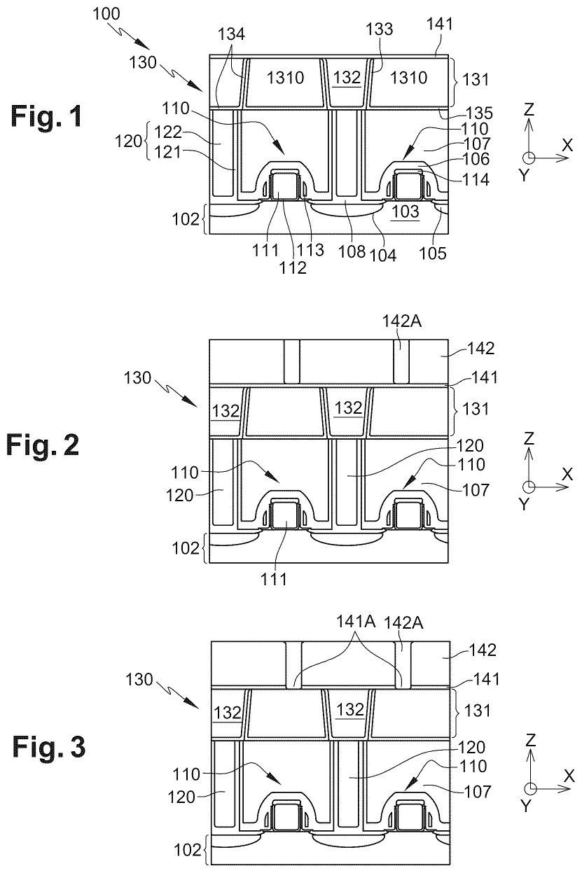

FIG. 1 is a longitudinal cross-section view schematically and partially showing an example of an electronic device 100.

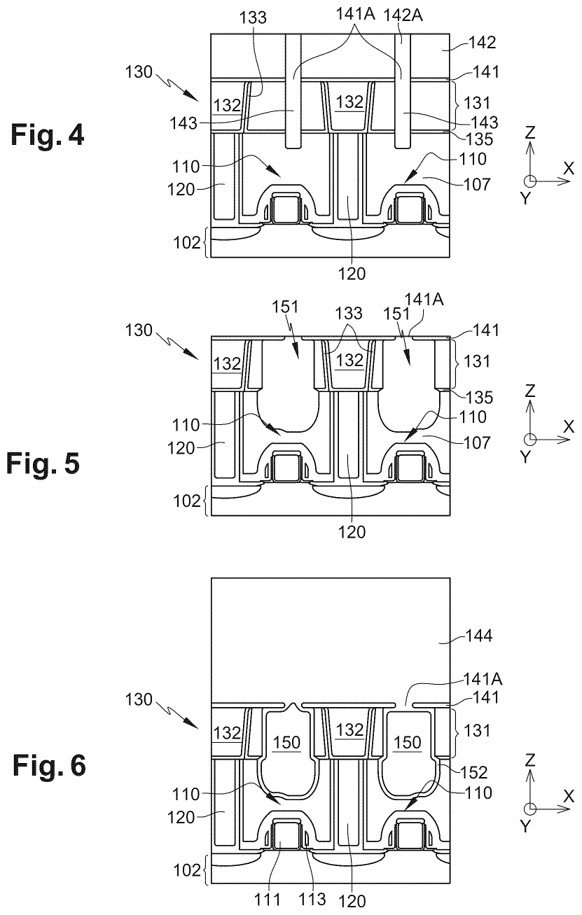

The electronic device 100 of FIG. 1 may form an initial structure for the method described in relation with FIGS. 2 to 10.

Electronic device 100 comprises a plurality of MOSFET transistors 110 formed on top and inside of a semiconductor substrate 102. In certain embodiments, substrate 102 is made of silicon or is a silicon-on-insulator or SOI layer. Substrate 102 extends along a plane XY, or main plane.

Although two transistors are illustrated in FIG. 1, any number of transistors and/or of other electronic components may be formed on top and/or inside of substrate 102. The transistors, or more broadly, the electronic components, may be positioned next to one another in the X and/or in the Y direction.

Each transistor 110 comprises a gate region 111 covering a channel-forming region 103, or channel region, formed in substrate 102. Channel region 103 is located between two doped semiconductor regions of substrate 102, respectively forming the drain region 104 and the source region 105 of transistor 110, or the source region 104 and the drain region 105 of transistor 110.

Gate region 111 may be made of polysilicon and/or a conductive material such as a rare-earth silicide, for example a titanium or cobalt silicide, or a combination of a plurality of these materials. Gate region 111 can be multi-layered, with for example a polysilicon layer and one (or a plurality of) layer(s) made of a conductive material. Gate region 111 is insulated from substrate 102 by a gate insulator 112. The gate insulator, or another insulating layer, may also cover the side walls of gate region 111. Gate insulator 112 may be made of a silicon oxide, such as silicon dioxide (SiO₂).

The flanks of gate region 111 are covered by gate spacers 113. Gate spacers 113 comprise one or a plurality of dielectric layers. In certain embodiments, gate spacers 113 comprise silicon oxide, silicon dioxide, silicon nitride (for example Si₃N₄), or a combination of a plurality of these materials. For example, gate spacers 113 may comprise a first silicon nitride layer, a second silicon dioxide layer on the first layer, and a third silicon nitride layer on the second layer. As illustrated in FIG. 1, gate spacers 113 may comprise a first layer and a second layer having each L-shaped profiles in longitudinal cross-section.

In certain embodiments, a cover layer 114 covers the upper surface of gate region 111. Cover layer 114 comprises an appropriate conductive material, such as, for example, titanium, titanium nitride, tantalum, tantalum nitride, cobalt silicide (CoSi₂), or a combination of a plurality of these materials.

In certain embodiments, a metal silicide layer 108, or silicide layer, is formed on each of the drain and source regions 104, 105. Such a silicide layer enables to strongly decrease the value of the electrical access resistance of the contacts 120 described hereafter, that is, the resistance between the drain and source regions and the contacts.

An etch stop layer 106 is formed on transistors 110, that is, at least on gate regions 111, source and drain regions 104, 105, and gate spacers 113. Etch stop layer 106 may be used to control the subsequent etch steps, to form contacts 120 for example. Etch stop layer 106 may comprise a nitride such as silicon nitride (for example Si₃N₄), a carbon silicon nitride, or any other appropriate material.

A pre-metal dielectric layer 107, or PMD layer, is formed on etch stop layer 106. In certain embodiments, PMD layer 107 comprises a silicon oxide, such as silicon dioxide (SiO₂). In other embodiments, PMD layer 107 comprises a silicon phosphide glass, known by the abbreviation “PSG” (Phospho-Silicon Glass), or a silicon borophosphide glass, known by the abbreviation “BPSG” (Borophospho-Silicon Glass). However, PMD layer 107 may comprise a combination of a plurality of these materials, or any other appropriate material.

Contacts 120 are formed through PMD layer 107 and etch stop layer 106 to physically and electrically contact source and drain regions 104, 105.

To form these contacts 120, openings are formed through PMD layer 107 and etch stop layer 106 at least all the way to silicide layer 108 if it is present, or all the way to source and drain regions 104, 105 otherwise, typically by an appropriate masking technique, such as photolithography, and then an appropriate etching technique. Then, a barrier layer 121 is conformally deposited on the inner walls and at the bottom of these openings. Barrier layer 121 comprises an appropriate conductive material such as tantalum, tantalum nitride, titanium, titanium nitride, or a combination of a plurality of these materials. Barrier layer 121 is formed by an appropriate method such as a chemical vapor deposition (CVD) technique, a physical vapor deposition (PVD) technique, an atomic layer deposition (ALD) technique, or by electroplating. Then, a conductive filler material 122 is formed on barrier layer 121 to fill the openings. In certain embodiments, conductive filler material 122 comprises tungsten, cobalt, copper, or a combination of a plurality of these materials. Conductive filler material 122 is formed by an appropriate method such as CVD, PVD, ALD or by electroplating. The upper portions of barrier layer 121 and of conductive filler material 122 may be removed with an appropriate planarization technique, such as a chemical mechanical polishing (CMP).

Thus, electrical contacts 120 run through PMD layer 107 to couple drain and source regions 104, 105 to an interconnection structure, a first metallization level 130 of which can be seen in FIG. 1.

First metallization level 130 comprises conductive elements 132, such as metal lines (elongated in the Y direction), insulated from one another by dielectric elements, or insulating elements 1310. These dielectric elements 1310 altogether form an intermetallic dielectric layer 131 (first intermetallic dielectric layer), or IMD layer 131. Conductive elements 132 are coupled to contacts 120, preferably positioned substantially in line with contacts 120.

First metallization level 130 may be formed by a subtractive process, for example for aluminum lines, or by a Damascene-type process, for example for copper lines.

An example of a subtractive process is described in the following. A conductive layer, for example made of aluminum, is deposited on PMD layer 107 and contacts 120. The deposition of conductive layer is performed by an appropriate method such as a CVD, PVD, or ALD technique, or by electroplating. Then, the conductive layer is etched through an etch mask, obtained for example by photolithography, the etching forming openings running through the conductive layer all the way to PMD layer 107. The etch mask is sized so that the remaining portions of the conductive layer, forming conductive elements 132, are positioned substantially in line with contacts 120. Then, the etch mask is removed. A protection layer 133 may then be deposited so as to cover the upper surfaces and the side walls of conductive elements 132, and it generally also covers the exposed surfaces of PMD 107 layer at the bottom of the openings. Protection layer 133 may be made of a nitride, such as silicon nitride, or any other appropriate material. Protection layer 133 may be deposited by a CVD technique, or any other appropriate technique. The portions of the protection layer which are located on the exposed surfaces of PMD layer 107 at the bottom of the openings can then be removed. Then, an IMD layer 131 is formed at least to fill the openings between conductive elements 132, forming insulating elements 1310. IMD layer 131 for example comprises a silicon oxide, such as silicon dioxide (SiO₂), or any other dielectric material. IMD layer 131 is deposited by an appropriate technique, such as a CVD technique. Excess portions of IMD 131 layer may be removed by means of a planarization, such as a CMP.

According to a variant of the described subtractive process, an initial protection layer may be formed on the conductive layer prior to etching thereof, in order to protect the underlying layers during the etching, the etching of the conductive layer comprising the etching of the initial protection layer through the etch mask, so that the initial protection layer only remains on the conductive elements after etching.

An example of a Damascene process is described in the following. An IMD layer 131 is deposited on PMD layer 107 and contacts 120. IMD layer 131 may be similar to the IMD layer described hereabove, as well as the IMD layer deposition technique. Then, IMD layer 131 is etched through an etch mask, obtained for example by photolithography, forming openings running through IMD layer 131. The remaining portions of IMD layer 131 form insulating elements 1310. The etch mask is sized so that the openings in IMD layer 131 are positioned substantially in line with contacts 120. The etch mask is removed. A protective layer 133 may then be deposited in the openings, so as to cover the side walls of the openings, and it also generally covers the bottoms of the openings and insulating elements 1310. Protection layer 133 may be similar to the protection layer described hereabove, as well as the technique for depositing the protection layer. The portions of protection layer 133 which are located at the bottom of the openings and on insulating elements 1310 may then be removed. Then, a barrier layer 134 is deposited in the openings, so as to cover the side walls and the bottoms of the openings, and it also generally covers insulating elements 1310. Barrier layer 134 comprises an appropriate conductive material such as tantalum, tantalum nitride, titanium, titanium nitride, or a combination of a plurality of these materials. Barrier layer 134 is formed by an appropriate method such as CVD, PVD, ALD, or by electroplating. Then, a conductive material, for example copper, is formed at least to fill the openings between insulating elements 1310, forming with barrier layer 134 conductive elements 132. Excess portions of the conductive layer and of barrier layer 134 located above insulating elements 1310 may be removed by means of a planarization such as a CMP.

According to a variant of the described Damascene process, an initial protection layer 135 may be formed on PMD layer 107 and contacts 120 prior to the deposition of the IMD layer, in order to protect the underlying layers during the etching of IMD layer 131, the etching of IMD layer 131 comprising the etching of the initial protection layer 135 through the etch mask, the initial protection layer 135 remaining under the unetched portions of IMD layer 131.

In both techniques, protection layer 133 is present on the flanks of conductive elements 132, which can protect conductive elements 132 during subsequent manufacturing steps, such an as etching to form cavities as described hereafter.

As an illustration, FIG. 1 shows conductive copper elements 132 obtained by the Damascene process. But they could also be aluminum conductive elements obtained by the subtractive process. The same numerical references have been used for similar elements in the description of the two processes.

As can be seen in FIG. 1, a protection layer 141 is formed on the first metallization level 130, that is, on conductive elements 132 and IMD layer 131. Protection layer 141, as well as the technique of deposition of protection layer 141, may be similar to the protection layer 133 described hereabove in relation with FIG. 1.

The initial structure of the manufacturing method described in relation with FIGS. 2 to 10 may not comprise protection layer 141, the deposition of this protective layer 141 being likely to form part of the manufacturing method.

FIG. 2, FIG. 3, FIG. 4, FIG. 5, FIG. 6, FIG. 7, FIG. 8, FIG. 9, and FIG. 10 are longitudinal cross-section views schematically and partially showing structures obtained at the end of successive intermediate steps of an example of a method of manufacturing an electronic device according to an embodiment.

FIG. 2 shows a structure obtained at the end of the forming of an etch mask 142 on protection layer 141. Etch mask 142 may be obtained by a photolithography technique.

Etch mask 142 is intended to be used to form cavities 150 in IMD layer 131 and PMD layer 107, between conductive elements 132, and optionally between contacts 120, as described hereafter in relation with FIGS. 3 to 7. Openings 142A in etch mask 142 may be formed at locations desirable to form these cavities, such as for example above the gate regions 111 of transistors 110.

FIG. 3 shows a structure obtained at the end of the etching of portions of protection layer 141 through the openings 142A of etch mask 142, the etched portions forming openings 141A (first openings) in protection layer 141. This etching is, for example, a dry etching, of plasma etching type.

FIG. 4 shows a structure obtained at the end of the etching of ports 143 (third ports) running through IMD layer 131 all the way into PMD layer 107, between two conductive elements 132. The etching is performed through the openings 142A of etch mask 142 and the openings 141A of protection layer 141. Ports 143 may be formed by means of an appropriate anisotropic etching, such as a dry etching, for example, of plasma etching type. The diameter of ports 143 may substantially correspond to the diameter of openings 141A in protection layer 141.

The etchings of FIGS. 3 and 4 may be carried out in a single etch step.

Etch mask 142 is then removed.

FIG. 5 shows a structure obtained at the end of the widening of ports 143 by etching, so as to form open cavities 151 in IMD layer 131 and PMD layer 107 between two conductive elements 132, and possibly between two contacts 120. The openings of open cavities 151 correspond to the openings 141A of protection layer 141. Open cavities 151 may be formed by means of an appropriate isotropic etching, advantageously selective of the material of IMD layer 131 and of PMD layer 107 with respect to the material of protection layer 141, to avoid etching protection layer 141. In certain embodiments, the isotropic etching is a wet etching, for example carried out with hydrofluoric acid (HF) that may be in vapor form, hydrochloric acid (HCl), potassium hydroxide (KOH), tetramethylammonium hydroxide (TMAH), sodium hydroxide (NaOH), nitric acid (HNO₃), buffered oxide etch (BOE), or a mixture of a plurality of these products.

The diameter of ports 143 may enable to define the dimensions of open cavities 151. For example, the larger the diameter of ports 143, the larger the average diameter of open cavities 151.

The protection layer 133 which is located on the side walls, or flanks, of conductive elements 132 may advantageously protect conductive elements 132 during the anisotropic etching and/or the isotropic etching.

The widening of ports 143 is advantageously carried out in such a way that all or part of open cavities 151 may be coupled together, forming a continuous open cavity in one or a plurality of directions of the XY plane between conductive elements 132, for example at least in the Y direction.

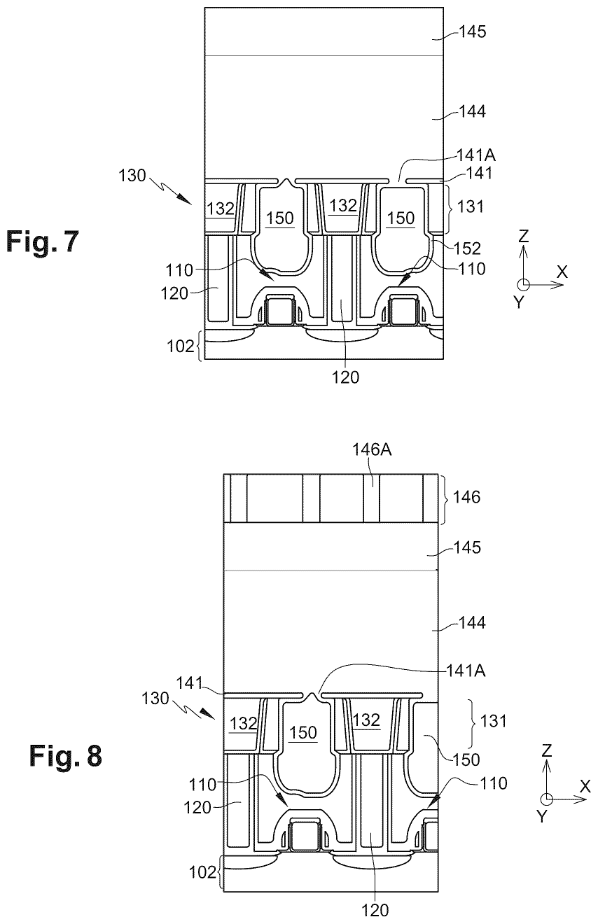

The longitudinal cross-section of FIGS. 5 and 6 shows a single port 143 between two adjacent conductive elements 132 in the X direction, and then a single open cavity 151 by widening of port 143 between two adjacent conductive elements 132 in the X direction. This cross-section corresponds to an example, and there may be formed a plurality of ports 143, and then a plurality of adjacent open cavities 151 coupled together in the X direction, and then a plurality of cavities 150 coupled together, between two adjacent conductive elements in the X direction, as illustrated in FIG. 11 described hereafter.

FIG. 6 shows a structure obtained at the end of the forming of an intermetallic dielectric layer 144 (second intermetallic dielectric layer), or IMD layer 144, on protection layer 141 and on the openings of open cavities 151, so as to close these open cavities 151, forming closed cavities 150, which will be designated as cavities (air gaps). IMD layer 144 may be formed by using materials and methods similar to those of IMD layer 131 as described hereabove. By passing through the openings 141A of protection layer 141, the dielectric material of IMD layer 144 may cover the inner surfaces of cavities 150 before closing open cavities 151, forming an inner coating 152 in cavities 150.

In certain embodiments, cavities 150 are above the gate regions 111 of transistors 110, and they may have a width greater than the combined width of gate region 110 and of gate spacers 113.

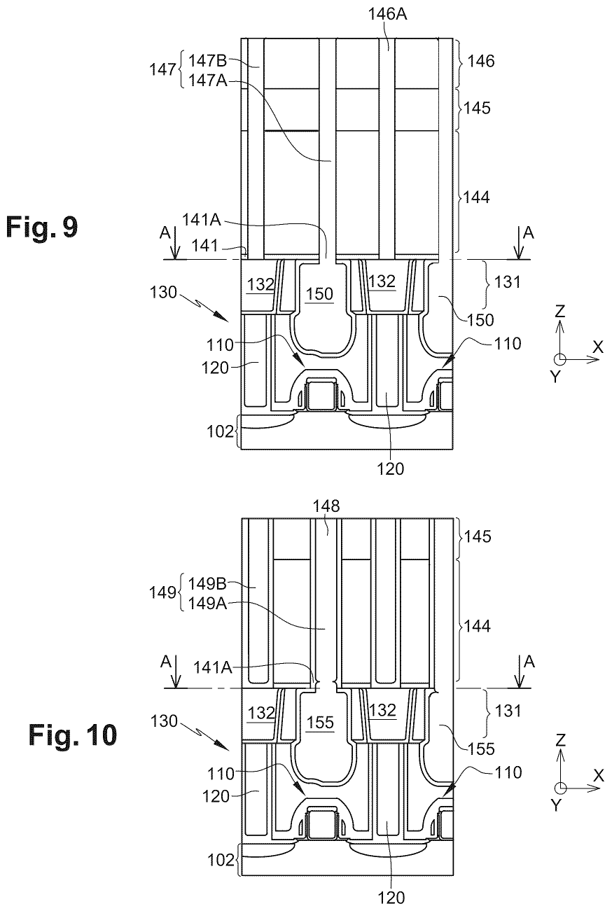

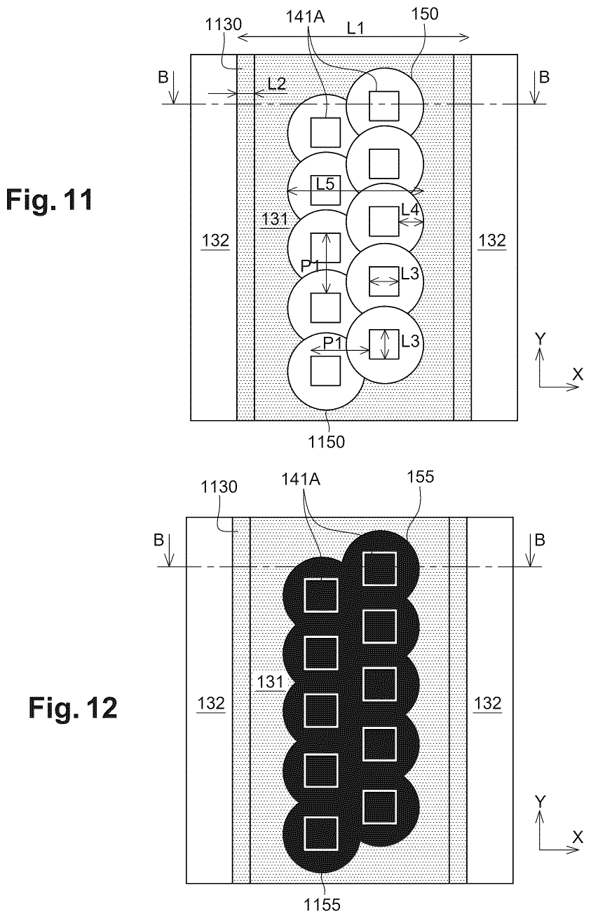

Preferably, the cavities 150 located between two adjacent conductive elements 132 are coupled together in one or a plurality of directions, forming one or a plurality of continuous extended cavities. In other words, cavities 150 positioned between a same pair of adjacent conductive elements 132 may form a continuous extended cavity, and other cavities 150 positioned between another pair of adjacent conductive elements 132 may form another continuous extended cavity. For example, the cavities may be coupled together in the transverse direction Y, or even also in the longitudinal direction X, as illustrated in FIGS. 11 and 12 described hereafter.

FIG. 7 shows a structure obtained at the end of the forming of a planarization layer 145, for example a layer made of a silicon oxide. This planarization layer is optional and may be omitted.

As a variant, instead of the electronic device 100 of FIG. 1, the manufacturing method may start from the structure shown in any of FIGS. 2 to 7, for example from the structure shown in FIG. 6 (with no planarization layer) or FIG. 7 (with a planarization layer).

FIG. 8 shows a structure obtained at the end of the forming of an etch mask 146 on planarization layer 145. Etch mask 146 may be obtained by a photolithography technique.

Openings 146A in etch mask 146 may be formed at desirable locations to form in IMD layer 144 ports 147 coupled to cavities 150 and to conductive elements 132.

FIG. 9 shows a structure obtained at the end of the etching of planarization layer 145, of IMD layer 144, and of protection layer 141 to form ports 147 running through these layers, the etching being carried out through the openings 146A of etch mask 146. Openings 147 comprise first ports 147A which are formed in line with cavities 150, and second ports 147B which are formed in line with conductive elements 132. First ports 147A enable to reopen cavities 150, to fill them with conductive material, and thus fill the continuous extended cavities, as described hereafter. The filled first ports form first vias, as described hereafter. For example, the first ports 147A are centered with the openings 141A of protection layer 141. The second ports 147B, once filled with conductive material, form second vias, as described hereafter.

Not all the cavities 150 of a same continuous extended cavity are necessarily coupled to a first port 147A. Indeed, since the cavities 150 of a single continuous extended cavity are coupled together, it may be sufficient to only have two first ports 147A to fill cavities 150 with conductive material, for example a first inlet port for the conductive material and a first outlet port for the conductive material. However, for example, according to the length of the continuous extended cavity, more than two first ports may be provided so that it can be properly filled.

FIG. 10 shows a structure obtained at the end of the filling of ports 147 with a conductive material 148, which for example comprises tungsten, forming conductive vias 149.

The filling is performed by means of an appropriate deposition technique, such as an ALD technique, or by a PVD or CVD technique, or by electroplating.

The first ports 147A enable to fill cavities 150 with conductive material 148, forming conductive regions 155, and the first ports 147A form first vias 149A once they have been filled, each first via 149A being coupled to one of conductive regions 155.

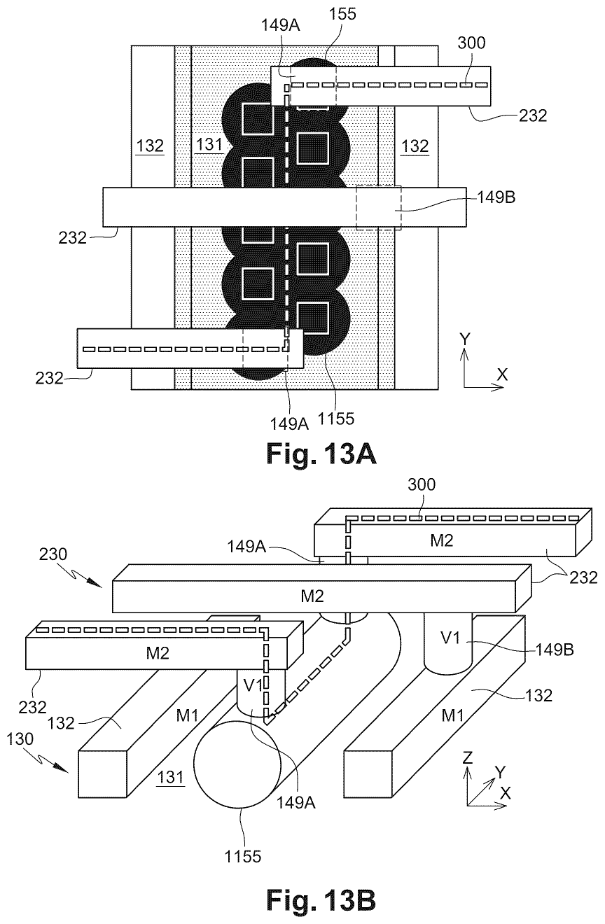

Since, between conductive elements 132, cavities 150 are coupled together in one or a plurality of directions, forming continuous extended cavities, conductive regions 155 are also coupled together, forming continuous conductive tracks, or conductive tracks (an example of a conductive track is shown in FIGS. 12, 13A, and 13B). In other words, conductive regions 155 positioned between a same pair of adjacent conductive elements 132 may form a conductive track, and other conductive regions 155 positioned between another pair of adjacent conductive elements 132 may form another conductive track. Each first via 149A is coupled to a conductive track.

Vias 149 further comprise second vias 149B which are coupled to conductive elements 132 and which take part in the interconnection of the conductive elements 132 of the first metallization level 130 with conductive elements of a second metallization level (shown in FIGS. 13A and 13B).

In the description of the manufacturing method described in relation with FIGS. 8 to 10, it has been considered that there is a planarization layer 145, but the manufacturing method may easily be adapted in the case where there is no planarization layer. For example, the etch mask 146 of FIG. 8 is then formed on IMD layer 144, and ports 147 and vias 149 run through IMD layer 144 and protection layer 141.

The top views of FIGS. 11 and 12 described in the following are views taken along a horizontal cross-section plane A-A shown in FIGS. 9 and 10, in the IMD layer 131 of the first metallization level 130.

FIG. 11 is a top view schematically and partially showing a structure that can be obtained at the end of the step shown in FIG. 9.

FIG. 11 illustrates an embodiment in which a plurality of cavities 150 are formed in IMD layer 131 between two conductive elements 132, and are coupled together both in the longitudinal X direction and in the transverse Y direction. A continuous extended cavity 1150 is obtained between the two conductive elements 132. For example, the continuous extended cavity 1150 extends substantially parallel to conductive elements 132. There has been shown inside of each cavity 150 the openings 141A of protection layer 141.

There have been shown in FIG. 11 only two conductive elements 132, although there may be others, as shown in FIG. 9. There may then be a plurality of continuous extended cavities 1150. FIG. 9 could correspond to a cross-section along the cross-section plane B-B shown in FIG. 11, which only runs through an opening 141A between the two conductive elements 132. There can indeed be seen in FIG. 9, as in FIG. 11, that each opening 141A is not necessarily centered with respect to the continuous extended cavity 1150 in the X direction. Thus, the cavity 150 of FIG. 9 may in fact correspond to a portion of continuous extended cavity 1150 seen in cross-section plane B-B.

In certain embodiments, IMD layer 131 has a length L1 between conductive elements 132, measured in the X direction, in the range from 0.2 μm to 5 μm. IMD layer 131 may comprise forbidden areas 1130 adjacent to each conductive element 132 which are preferably not etched to form cavities 150, in order to avoid damaging conductive elements 132. For example, forbidden areas 1130 have a length L2, measured in the X direction, in the range from 0.01 μm to 1 μm.

The shown openings 141A have a square shape. In certain embodiments, openings 141A have a dimension L3, measured in each of the X and Y directions, in the range from 50 nm to 300 nm. The shown shape is not limiting and openings 141A may have any appropriate shape, such as rectangular shapes, circular shapes, oval shapes, triangular shapes, hexagonal shapes, octagonal shapes, or the like, and it is possible for all openings 141A not to have the same shapes.

Openings 141A have been shown as arranged in staggered fashion. Generally, the arrangement of ports 143 corresponds to the arrangement of openings 141A, so that ports 143 can also be arranged in staggered fashion. This staggered shape of ports 143 can be advantageous so that the cavities 150 formed during the isotropic etching are coupled together and form continuous extended cavity 1150. In the shown example, openings 141A are arranged in two columns between conductive elements 132, although they could be arranged in any appropriate number of columns, for example from one to five columns. Further, in the shown example, the openings 141A of a column are offset in the Y direction with respect to the openings 141A of the other column. In certain embodiments, openings 141A are arranged with a pitch P1 in the range from 50 nm to 300 nm, or from 50 nm to 200 nm. However, openings 141A may be arranged according to any appropriate pattern. Thus, the shown configuration is not limiting and other configurations are possible, since this enables to form a continuous extended cavity.

Each cavity 150 has been shown in simplified form with a circular cross-section centered with respect to the opening 141A of protection layer 141, the circles of the cavities overlapping. In certain embodiments, the distance L4 between opening 141A and the wall of cavity 150 is in the range from 0 to 500 nm, this distance being for example induced by the isotropic etching time. In practice, the cross-section of each cavity may have a different shape, which is not perfectly circular, and it may not be perfectly centered with respect to the opening 141A of protection layer 141. More generally, cavities 150 may have various shapes, with cross-sections which are not necessarily uniform along the level of the cross-section plane.

In certain embodiments, the continuous extended cavity 1150 has a length L5, measured in the X direction, in the range from 0.1 μm to 5 μm.

The anisotropic etching for forming ports 143 and the isotropic etching for widening ports 143 and thus forming cavities 150, may be carried out so that the length L5 of continuous extended cavity 1150 is smaller than or equal to the length L1 of IMD layer 131 between conductive elements 132 minus the added lengths L2 of the two forbidden areas 1130. Further, ports 143 may be positioned so that continuous extended cavity 1150 is substantially centered in IMD layer 131 between conductive elements 132.

The cavities 150 shown in FIG. 11 are thus distributed in staggered fashion in both X and Y directions and overlap, but other configurations can be envisaged, since a continuous extended cavity is formed in the longitudinal X direction and/or in the transverse Y direction.

FIG. 12 is a top view schematically and partially showing an electronic device that can be obtained at the end of the step shown in FIG. 10.

The electronic device of FIG. 12 corresponds to the structure of FIG. 11, after the filling of cavities 150 with conductive material, forming conductive regions 155, the conductive regions altogether forming a conductive track 1155. The rest of the description of FIG. 11 may apply to FIG. 12.

It can be seen that conductive track 1155 extends substantially parallel to conductive elements 132.

There have been shown in FIG. 12 only two conductive elements 132, although there may be others, as shown in FIG. 10. There can then be a plurality of conductive tracks 1155. FIG. 10 may correspond to a cross-section along the cross-section plane B-B shown in FIG. 12, which runs through a single opening 141A between the two conductive elements 132. It can indeed be seen in FIG. 10, as in FIG. 12, that each opening 141A is not necessarily centered with respect to conductive track 1155 in the X direction. Thus, the conductive region 155 of FIG. 10 may in fact correspond to a portion of conductive track 1155 seen in the cross-section plane B-B of FIG. 12.

FIG. 13A and FIG. 13B are top and three-dimensional views schematically and partially showing an electronic device according to an embodiment, such as the electronic device of FIG. 12, additionally with a second metallization level.

More precisely, FIGS. 13A and 13B show the electronic device of FIG. 12, with additionally a second metallization level 230 (M2) comprising second metal lines 232 above the first metallization level 130 (M1) which comprises first metal lines 132 in IMD layer 131. Second vias 149B couple the first metal lines 132 with some of the second metal lines 232, while the first vias 149A may couple other second metal lines 232 together via conductive track 1155, creating an interconnection circuit 300. Thus, the metallization of cavities 150 enables to create an additional interconnection level.

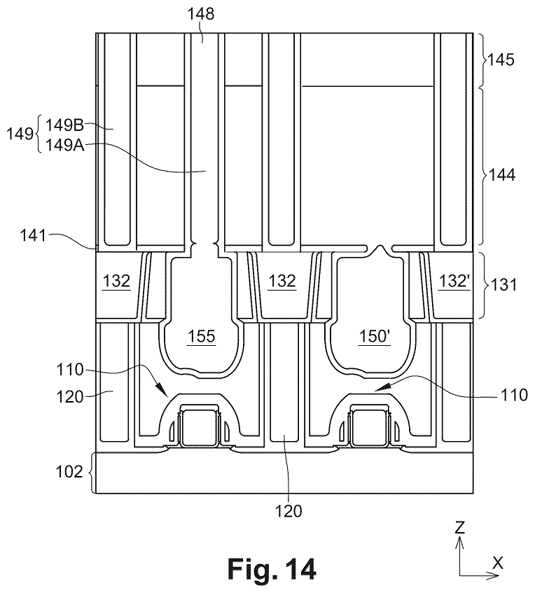

FIG. 14 is a longitudinal cross-section view schematically and partially showing an electronic device according to another embodiment.

In this embodiment, the electronic device comprises other cavities 150′ between two other adjacent conductive elements, that is, between a pair of conductive elements 132, 132′ different from the pair of conductive elements 132 described in FIGS. 1 to 10. Only another cavity 150′ has been shown, but there are a plurality thereof, at least in the transverse Y direction. Two different pairs of conductive elements may comprise a same conductive element 132, as shown in FIG. 14. As a variant, it is possible for two different pairs of conductive elements not to comprise the same conductive element. The other cavities 150′ are coupled together, at least in the Y direction, but they are not filled with conductive material 148.

In other words, in the method, no port 147 has been formed all the way to these other cavities 150′. The etch mask 146 of FIG. 8 may be adapted so that it comprises no openings 146A in line with the other cavities 150′.

Thus, an electronic device may comprise both conductive regions 155 coupled together to form a conductive track between two conductive elements, and cavities 150′ not filled with conductive material and coupled together to form a continuous extended cavity between two other conductive elements.

It can thus be seen that the embodiments enable to form an additional interconnection level, by using each conductive track and the first vias coupled to this track, and this, by adapting a standard electronic device manufacturing process. In particular, an air gap forming process may be used, simply by adjusting the etch parameters to obtain cavities coupled together, and thus a continuous extended cavity, and a BEOL process may be used, by modifying the etch mask used to form the ports for forming the conductive vias between two metallization levels, so that some of the ports are used to reopen the cavities to fill them with metal at the same time as the conductive vias are formed.

An application of the embodiments concerns the control of the forming of the cavities. By metallizing the cavities and by coupling them to conductive vias, an electrical circuit can be formed, and the continuity of the metallized cavities can be controlled, for example by controlling the conductivity of the electrical circuit formed by the conductive track and the vias.

Various embodiments and variants have been described. Those skilled in the art will understand that certain features of these various embodiments and variants may be combined, and other variants will occur to those skilled in the art. In particular, in the embodiments, MOSFET transistors have been shown as electronic components in the electronic device. This is not limiting, and the described embodiments can apply to an electronic device comprising other electronic components, for example other types of transistors and/or diodes. More generally, the described embodiments can apply to any electronic device comprising electronic components and an interconnection structure.

Finally, the practical implementation of the described embodiments and variants is within the abilities of those skilled in the art based on the functional indications given hereabove.

What is claimed is:

1. A method of manufacturing an electronic device, the method comprising:
providing a structure comprising a semiconductor substrate on top and inside of which are formed electronic components, first conductive elements above the semiconductor substrate, a first intermetallic dielectric layer between the first conductive elements, cavities in the first intermetallic dielectric layer between two first adjacent conductive elements among the first conductive elements, and a second intermetallic dielectric layer over the first intermetallic dielectric layer and the cavities, the cavities being coupled together so as to form a continuous extended cavity between the two first adjacent conductive elements;
forming first ports and second ports running through the second intermetallic dielectric layer, the first ports each extending to one of the cavities and the second ports each extending to one of the first conductive elements; and
filling the first and second ports with a conductive material, the filling the first ports being performed so as to fill the cavities, forming conductive regions coupled together, and thus a conductive track, the filling the first ports also forming first conductive vias coupled to the conductive track, and the filling the second ports forming second conductive vias coupled to the first conductive elements.

2. The method according to claim 1, wherein the providing the structure includes forming the cavities, which comprises:
forming third ports running through the first intermetallic dielectric layer between the two first adjacent conductive elements, the forming the third ports comprising a first anisotropic etching and/or a first dry etching;
widening the third ports so as to form open cavities coupled together in the first intermetallic dielectric layer, the widening the third ports comprising an isotropic etching and/or a wet etching; and
forming the second intermetallic dielectric layer over the open cavities and the first intermetallic dielectric layer, so as to close the open cavities.

3. The method according to claim 2, comprising, prior to the forming the third ports, depositing a first protection layer over the first intermetallic dielectric layer and the first conductive elements, followed by forming first openings in the first protection layer, the third ports being formed in line with the first openings, the forming the first openings comprising a second anisotropic etching and/or a second dry etching.

4. The method according to claim 1, wherein the forming the first and second ports comprises an anisotropic etching and/or a dry etching.

5. The method according to claim 1, wherein the provided structure comprises other cavities in the first intermetallic dielectric layer between two other first adjacent conductive elements among the first conductive elements, the second intermetallic dielectric layer also extending over the other cavities, the other cavities being coupled together and being not filled with the conductive material, so as to form a second continuous extended cavity between the two other first adjacent conductive elements.

6. The method according to claim 1, wherein the first conductive elements are insulated from one another by the first intermetallic dielectric layer in a first direction of a plane substantially parallel to the plane of the semiconductor substrate, and the conductive regions are coupled together in a second direction of the plane perpendicular to the first direction.

7. The method according to claim 1, wherein lateral edges of the first conductive elements are protected by a second protection layer.

8. The method according to claim 1, wherein the conductive regions also extend in a pre-metal dielectric layer located between the semiconductor substrate and the first intermetallic dielectric layer.

9. The method according to claim 1, wherein the conductive track and the first conductive vias are disposed in a circuit for controlling an electrical continuity between the conductive regions.

10. An electronic device comprising:
a semiconductor substrate on top and inside of which are arranged electronic components;
first conductive elements above the semiconductor substrate;
a first intermetallic dielectric layer between the first conductive elements;
conductive regions extending at least across a thickness of the first intermetallic dielectric layer between two first adjacent conductive elements among the first conductive elements, the conductive regions being coupled together in a shape of a conductive track;
a second intermetallic dielectric layer over the first intermetallic dielectric layer, the first conductive elements, and the conductive track;
first conductive vias running through the second intermetallic dielectric layer and coupled to the conductive track; and
second conductive vias running through the second intermetallic dielectric layer and coupled to the first conductive elements.

11. The device according to claim 10, further comprising other cavities in the first intermetallic dielectric layer between two other first adjacent conductive elements among the first conductive elements, the second intermetallic dielectric layer also extending over the other cavities, the other cavities being coupled together so as to form a continuous extended cavity between the two other first adjacent conductive elements.

12. The device according to claim 10, wherein the first conductive elements are insulated from one another by the first intermetallic dielectric layer in a first direction of a plane substantially parallel to the plane of the semiconductor substrate, and the conductive regions are coupled together in a second direction of the plane perpendicular to the first direction.

13. The device according to claim 12, wherein the conductive regions are also coupled together in the first direction of the plane.

14. The device according to claim 10, wherein lateral edges of the first conductive elements are protected by a second protection layer.

15. The device according to claim 10, wherein the conductive regions also extend in a pre-metal dielectric layer located between the semiconductor substrate and the first intermetallic dielectric layer.

16. The device according to claim 15, wherein contacts running through the pre-metal dielectric layer are coupled to the electronic components and to the first conductive elements, the conductive regions also extending between the contacts.

17. The device according to claim 10, wherein the conductive regions comprise tungsten and/or the first conductive elements comprise copper or aluminum.

18. The device according to claim 10, wherein the first conductive elements and the first intermetallic dielectric layer are a first metallization level of an interconnection structure.

19. The device according to claim 10, wherein a second metallization level comprises second conductive elements coupled to the first conductive elements by the second conductive vias, and other second conductive elements coupled to the conductive track by the first conductive vias.

20. The device according to claim 10, wherein the conductive track and the first conductive vias are disposed in a circuit for controlling an electrical continuity between the conductive regions.
